(19) United States
(12) Patent Application Publication
(10) Pub. No.: US 2022/0195586 A1
(43) Pub. Date: Jun. 23, 2022

(54) SUBSTRATE HOLDER FOR MASS PRODUCTION OF SURFACE-ENHANCED RAMAN SCATTERING SUBSTRATES

(71) Applicant: Tsinghua University, Beijing (CN)

(72) Inventors: Zhengjun ZHANG, Beijing (CN); Yihang FAN, Beijing (CN)

(21) Appl. No.: 17/132,210

(22) Filed: Dec. 23, 2020

(51) Int. Cl. C23C 14/50; C23C 14/02; C23C 14/28; C23C 14/14

(52) U.S. Cl. CPC C23C 14/50; C23C 14/14; C23C 14/28; C23C 14/021

(57) ABSTRACT

In the field of trace organic matter detection, a substrate holder for mass production of surface-enhanced Raman scattering (SERS) substrates includes a ring-shaped body and a support frame thereof. A plurality of cones are disposed on the ring-shaped body, and a plurality of substrates are pasted on both surfaces of each cone. The substrate holder allows for simultaneous deposition of silver nanorods on a plurality of substrates by glancing angle deposition method. An array film composed of the silver nanorods of a plurality of substrates has good product homogeneity, and the production efficiency of a traditional preparation method can be improved.

### TECHNICAL FIELD

The disclosure belongs to the technical field of trace organic matter detection, and in particular, relates to a substrate holder for mass production of surface-enhanced Raman scattering (SERS) substrates.

### BACKGROUND

Surface-enhanced Raman scattering (SERS), as a trace matter detection approach, has been widely used in the fields of environmental pollutant detection, food safety monitoring, disease diagnoses and medical care, etc. for its advantages such as high sensitivity, rapid detection, low cost and non-destructive analysis. High sensitive SERS substrates are typically prepared from noble metals such as gold, silver or copper, where silver nanostructured substrates presented the most outstanding SERS effects. Nobel metals are expensive, and the method of electron beam evaporation may result in wasting of abundant raw materials as the raw materials were mostly deposited on the chamber wall due to spherical spatial diffusion. Meanwhile, this will induce insufficient production of SERS substrates as substrates with only couple of inches in diameter can be produced in a typical process.

To overcome the shortcoming, the disclosure follows a glancing angle deposition technique as the basic principle, where the direction of a beam from an evaporation source forms an angle of 86-87 degrees with a substrate's normal direction, and a substrate holder with circular arc structures is employed to paste more substrates, so that evaporated raw material can be used fully and the included angle of desired 86-87 degrees between each substrate's normal direction and the evaporation beam can be guaranteed. The holder will enable mass production of SERS substrates with homogeneous nanostructures and outstanding detecting performance

### SUMMARY

The disclosure aims to design a substrate holder for mass production of surface-enhanced Raman scattering (SERS) substrates.

To achieve the above objective, the disclosure adopts the following technical solution: a substrate holder for mass production of SERS substrates includes a ring-shaped body and a support frame thereof. A plurality of cones are disposed on the ring-shaped body, and a plurality of substrates are pasted on both surfaces of each cone.

Upper and bottom edges of each cone are circular curves.

All the cones are located in a vertical direction.

Each circular curve has a cone angle of 6-8 degrees, and a bisector of the cone angle is in the vertical direction.

A method for preparing SERS substrates with the substrate holder includes the following steps:
(1) preprocessing substrates;
(2) pasting the preprocessed substrates on the substrate holder;
(3) aligning the substrate holder to an evaporation source;
(4) vacuumizing an electron beam evaporation chamber; and
(5) depositing a slanted nanorod array film on the substrates on the substrate holders to form SERS substrates.

Further, in step (1), the preprocessing includes ultrasonic cleaning of single side polished silicon substrates using acetone, absolute ethyl alcohol and deionized water in sequence, and drying of the substrates in the air.

Further, in step (2), the substrates are uniformly distributed on two surfaces of the cones.

Further, in step (3), the evaporation source is a crucible which is located under the center of a circle of the ring-shaped body; and the direction of a beam from the evaporation source forms an angle of 86 degrees with each substrate's normal direction.

Further, in step (4), the electron beam evaporation chamber has a vacuum degree of 4*10⁻⁴ Pa.

Further, in step (5), the depositing is carried out at room temperature with metal silver as a target material, and a deposition rate of the silver is controlled at 5 Å/s, such that a slanted silver nanorod array film having a length of about 600 nm in total is deposited on the substrates of the substrate holder.

The disclosure has the following advantages: the substrate holder disclosed herein allows for simultaneous deposition of silver nanorods on a plurality of substrates by a glancing angle deposition method. An array film composed of the silver nanorods of a plurality of substrates has good product homogeneity, and the production efficiency of a traditional preparation method can be improved.

### BRIEF DESCRIPTION OF THE DRAWINGS

FIG. 1 is an external view of a substrate holder according to an example of the present disclosure.

FIG. 2 is a scanning electron microscope image of a silver nanorod array SERS substrate deposited according to an example of the present disclosure.

FIG. 3 is an enhanced Raman signal chart of R6G molecules of a silver nanorod array prepared according to an example of the present disclosure.

### DETAILED DESCRIPTION

According to the present disclosure, a plurality of silver nanorod array surface-enhanced Raman scattering (SERS) substrates may be deposited simultaneously on a substrate holder by a glancing angle deposition method.

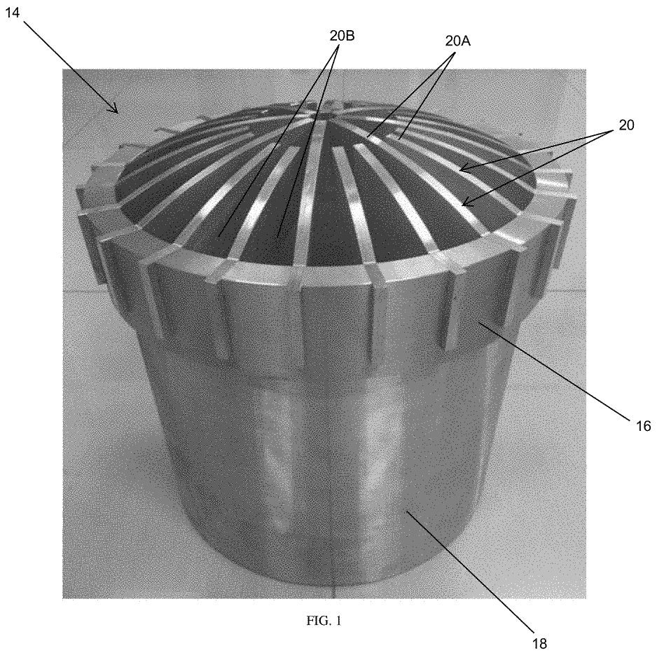

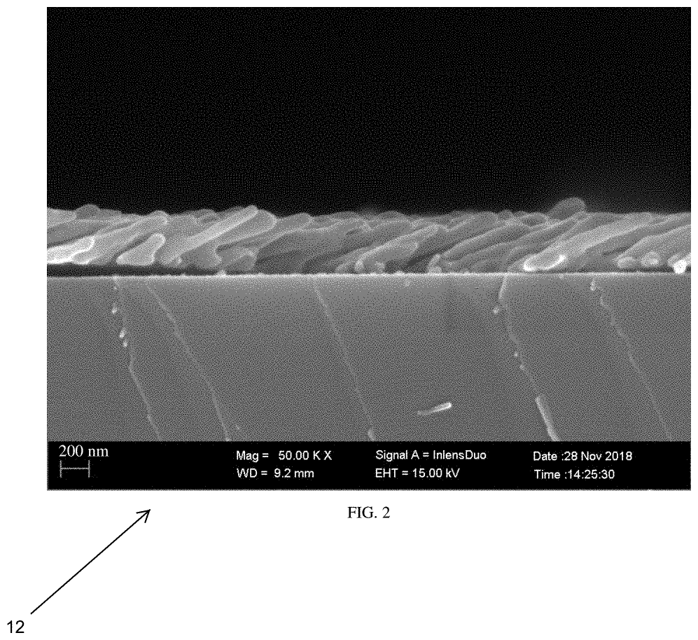

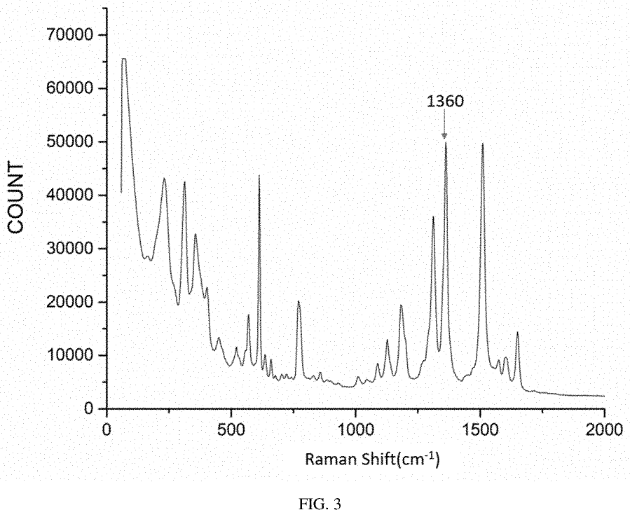

The disclosure will be described in detail in conjunction with FIG. 1 to FIG. 3 and an example. The following example is illustrative rather than limiting, and the protection scope of the disclosure cannot be limited by the following example.

### EXAMPLE 1

(1) Single side polished silicon substrates were subjected to ultrasonic cleaning using acetone, absolute ethyl alcohol and deionized water in sequence, and dried in the air.

(2) The preprocessed substrates were pasted on a substrate holder.

(3) The center of outer circle of a ring-shaped body of the substrate holder was aligned to a crucible.

(4) At room temperature, metal silver was used as a target material, and a chamber of a two-electron beam evaporation coating machine was vacuumized to a vacuum degree of 4*10⁻⁴ Pa.

(5) Adjustment was performed, and a deposition ratio of the silver was controlled at 5 Å/s such that a slanted silver nanorod film having a length of about 600 nm in total was deposited on the substrates of the substrate holder;

(6) A 10⁻⁵ mol/L R6G solution was prepared.

(7) The SERS substrates prepared in steps (1) to (5) were immersed in the solution to be detected prepared in step (6) for 30 minutes.

(8) The SERS substrates with trace amount of R6G absorbed thereon in step (6) were placed in a Raman spectrometer, and a light source with a wavelength of 785 nm was selected for measurement of Raman spectra.

It could be observed that peak intensity R6G signals of several substrates were basically the same, and it could be seen that the silver nanorod arrays on the substrates were almost the same in morphology, indicating that the SERS substrates prepared with the sample holder had almost the same effects. Thus, the expected objective was achieved.

The above example presents a detailed description of the technical solution of the present disclosure. Apparently, the disclosure is not limited to the described example. Those skilled in the art can also make various changes based on the example of the present disclosure, but any change that is equivalent or similar to the disclosure shall fall within the protection scope of the present disclosure.

1. A substrate holder for mass production of surface-enhanced Raman scattering (SERS) substrates, comprising a ring-shaped body and a support frame thereof, and a plurality of cones disposed on the ring-shaped body, wherein two surfaces of each cone are used to paste a plurality of substrates thereon.

2. The substrate holder according to claim 1, wherein upper and bottom edges of each cone are circular curves.

3. The substrate holder according to claim 1, wherein all the cones are located in a vertical direction.

4. The substrate holder according to claim 2, wherein each circular curve has a cone angle of 6-8 degrees, and a bisector of the cone angle is in the vertical direction.

5. A method for preparing SERS substrates with the substrate holder according to claim 1, comprising the following steps:
(1) preprocessing substrates;
(2) pasting the preprocessed substrates on the substrate holder;
(3) aligning the substrate holder to an evaporation source;
(4) vacuumizing an electron beam evaporation chamber; and
(5) depositing a slanted nanorod array film on the substrates on the substrate holders to form SERS substrates.

6. A method for preparing SERS substrates with the substrate holder according to claim 2, comprising the following steps:
(1) preprocessing substrates;
(2) pasting the preprocessed substrates on the substrate holder;
(3) aligning the substrate holder to an evaporation source;
(4) vacuumizing an electron beam evaporation chamber; and
(5) depositing a slanted nanorod array film on the substrates on the substrate holders to form SERS substrates.

7. A method for preparing SERS substrates with the substrate holder according to claim 3, comprising the following steps:
(1) preprocessing substrates;
(2) pasting the preprocessed substrates on the substrate holder;
(3) aligning the substrate holder to an evaporation source;
(4) vacuumizing an electron beam evaporation chamber; and
(5) depositing a slanted nanorod array film on the substrates on the substrate holders to form SERS substrates.

8. A method for preparing SERS substrates with the substrate holder according to claim 4, comprising the following steps:
(1) preprocessing substrates;
(2) pasting the preprocessed substrates on the substrate holder;
(3) aligning the substrate holder to an evaporation source;
(4) vacuumizing an electron beam evaporation chamber; and
(5) depositing a slanted nanorod array film on the substrates on the substrate holders to form SERS substrates.

9. The method according to claim 5, wherein in step (1), the preprocessing comprises ultrasonic cleaning of single side polished silicon substrates using acetone, absolute ethyl alcohol and deionized water in sequence, and drying of the substrates in the air.

10. The method according to claim 6, wherein in step (1), the preprocessing comprises ultrasonic cleaning of single side polished silicon substrates using acetone, absolute ethyl alcohol and deionized water in sequence, and drying of the substrates in the air.

11. The method according to claim 7, wherein in step (1), the preprocessing comprises ultrasonic cleaning of single side polished silicon substrates using acetone, absolute ethyl alcohol and deionized water in sequence, and drying of the substrates in the air.

12. The method according to claim 8, wherein in step (1), the preprocessing comprises ultrasonic cleaning of single side polished silicon substrates using acetone, absolute ethyl alcohol and deionized water in sequence, and drying of the substrates in the air.

13. The method according to claim 5, wherein in step (2), the substrates are uniformly distributed on two surfaces of the cones.

14. The method according to claim 6, wherein in step (2), the substrates are uniformly distributed on two surfaces of the cones.

15. The method according to claim 7, wherein in step (2), the substrates are uniformly distributed on two surfaces of the cones.

16. The method according to claim 8, wherein in step (2), the substrates are uniformly distributed on two surfaces of the cones.

17. The method according to claim 5, wherein in step (3), the evaporation source is a crucible which is located under the center of a circle of the ring-shaped body; and the direction of a beam from the evaporation source forms an angle of 86 degrees with each substrate's normal direction.

18. The method according to claim 6, wherein in step (3), the evaporation source is a crucible which is located under the center of a circle of the ring-shaped body; and the direction of a beam from the evaporation source forms an angle of 86 degrees with each substrate.

19. The method according to claim 5, wherein in step (4), the electron beam evaporation chamber has a vacuum degree of 4*10⁻⁴ Pa.

20. The method according to claim 5, wherein in step (5), the depositing is carried out at room temperature with metal silver as a target material, and a deposition rate of the silver is controlled at 5 Å/s such that a slanted silver nanorod array film having a length of about 600 nm in total is deposited on the substrates of the substrate holder.
